(19) United States
(12) Patent Application Publication
(10) Pub. No.: US 2011/0298074 A1
(43) Pub. Date: Dec. 8, 2011

(54) SOLID-STATE IMAGING ELEMENT AND ELECTRONIC INFORMATION DEVICE

(75) Inventor: Daisuke Funao, Osaka (JP)

(73) Assignee: SHARP KABUSHIKI KAISHA, Osaka (JP)

(21) Appl. No.: 13/110,227

(22) Filed: May 18, 2011

(30) Foreign Application Priority Data
Jun. 8, 2010 (JP) 2010-131528

(51) Int. Cl. H01L 31/0232

(52) U.S. Cl. 257/432; 257/E33.055

(57) ABSTRACT

A solid-state imaging element according to the present invention includes a plurality of light receiving sections formed in a pixel array, each light receiving section constituted of a semiconductor element for performing a photoelectric conversion on and capturing an image of image light from a subject, the solid-state imaging element further including: a light shielding wall or a reflection wall provided therein for pixel separation, in between the light receiving sections adjacent to one another in a plan view on a light entering side from the light receiving sections; and a color filter wherein at least a part of the color filter is embedded between the light shielding walls or the reflection walls, in such a manner to correspond to each of the plurality of light receiving sections, so that the distance between the color filter and a substrate can be shortened.

This nonprovisional application claims priority under 35 U.S.C. §119 (a) to Patent Application No. 2010-131528 filed in Japan on Jun. 8, 2010, the entire contents of which are hereby incorporated by reference.

### BACKGROUND OF THE INVENTION

1. Field of the Invention

The present invention relates to a solid-state imaging element comprising semiconductor elements for performing a photoelectric conversion on, and capturing an image of, image light from a subject; and an electronic information device, such as a digital camera (e.g., a digital video camera or a digital still camera), an image input camera (e.g., a monitoring camera), a scanner, a facsimile machine, a television telephone device and a camera-equipped cell phone device, including the solid-state imaging element as an image input device used in an imaging section.

2. Description of the Related Art

Conventional solid-state imaging elements of this type include CCD solid-state imaging elements and CMOS solid-state imaging elements, which include a mechanism for separating incident light into different colors (e.g., RGB) of a plurality of wavelength ranges by a color filter. Among the various kinds of performance for solid-state imaging elements with the object of obtaining a color image, light receiving sensitivity and color reproducibility are important kinds of performance. A mixture of colors is a primary factor in the decrease of color reproducibility. Reference 1, for example, discloses a way of restraining this problem by using a method for covering a photosensitive element with a light-shielding conductive material.

FIG. 13 is a plan view showing an example of an essential part structure of a conventional solid-state imaging element disclosed in Reference 1.

In a conventional solid-state imaging element 100 as shown in FIG. 13, a light shielding body 101 is arranged in the periphery of an imaging element, or a photosensitive element 102, covering a region between the photosensitive element 102 and an adjacent circuit. The light shielding body 101 is shown with a frame body of a square external form in a plan view; however, it should be noted that this is shown for explanatory purposes only. The light shielding body 101 may have any shape as long as it can substantially protect the adjacent photosensitive element 102 and/or other adjacent circuit (not shown) from cross talk. For example, the external shape of the light shielding body 101 includes, not only a square, but also an oval, circle, rectangle, octagon and the like. Further, the light shielding body 101 does not have to surround the photosensitive element 102 completely, and it is thus also possible for the light shielding body 101 to surround the periphery of the photosensitive element 102 discontinuously.

The photosensitive element 102 may be any element as long as it produces an electric current when exposed to an optical energy. For example, the photosensitive element 102 may be a PN junction photodiode, a PNP photodiode, or an NPN photodiode. Alternatively, in order to make an element equivalent to one of those elements, the photosensitive element 102 may be made by implanting impurity ions into a substrate using an ion implantation method. It is also possible to use a PNP photodiode and constitute the photosensitive element 102 with a PIN layer formed in an N-type region, for example. In this case, the N-type region is formed in the upper part of a P-type semiconductor substrate.

Light coming from the outside of the light shielding body 101 is reflected by the light shielding body 101, resulting in preventing or reducing the influence of the light coming from the outside of the light shielding body 101 on the photosensitive element 102. This action is particularly effective against light with an oblique angle arriving onto the surface of the photosensitive element 102, and this action can prevent the photosensitive element 102 from being influenced by light coming from an adjacent cell. Furthermore, this action can prevent light to be detected by the photosensitive element 102 from influencing an adjacent cell.

FIG. 14 is a longitudinal cross sectional view showing an example of an essential part structure of a conventional solid-state imaging element disclosed in Reference 2.

In a solid-state imaging element 200 including a lamination layer film 203 above a semiconductor substrate 202 including a light receiving section 201, as shown in FIG. 14, the efficiency for preventing reflection is improved so that the loss of incident light can be prevented and the efficiency for a photoelectric conversion in the light receiving section 201 can be improved. To that end, a lamination layer film 203 above a semiconductor substrate 201 has a two-layered structure, in which at least each of a first film with a high refractive index and a second film with a low refractive index is arranged in an adjacent manner from the side closer to a semiconductor substrate 202. An n-type impurity diffusion layer constituting the light receiving section 201 has a two-layered structure with an n-type impurity diffusion layer 201a and an n⁻-type impurity diffusion layer 201b.

A plurality of color filters 204 is formed on the lamination layer film 203. A microlens 205 is formed on the color filter 204 so that incident light from a back surface can be efficiently guided to an electric charge generating region, or the light receiving section 201. Each color filter 204 is configured to allow light of a different wavelength band to pass through it. A light shielding member 206 is formed at a bottom part of the color filter 204 and in between adjacent color filters 204 in order to prevent a mixture of colors. For example, W, Mo, Al (aluminum) or a black filter is used as a material for not transmitting light to be the light shielding member 206.
Reference 1: Japanese Laid-Open Publication No. 2006-237576
Reference 2: Japanese Laid-Open Publication No. 2008-182166

### SUMMARY OF THE INVENTION

As described above, a mixture of colors is a primary factor in the decrease of color reproducibility while the tendency is such that the area for pixels is being reduced and the number of pixels is being increased in image sensors. Shortening of the distance between adjacent pixels results in the increase in light which causes a mixture of colors.

The mixture of colors in the conventional solid-state imaging element 100 disclosed in Reference 1 will be described based on FIGS. 15(a) and 15(b).

In FIG. 15(a), oblique lights L1 to L3 pass through a microlens 112 and a color filter 110, and subsequently they pass in between light shielding bodies 101 to be photoelectrically converted into electrons E1 to E3 by the photosensitive element 102. The electrons E1 to E3 are all accumulated in the region of the photosensitive element 102. However, in such a case where the area for pixels is reduced, the number of pixels is increased, and the distance between adjacent pixels becomes shorter, although the oblique lights L1 to L3 pass through the microlens 112 and the color filter 110, and subsequently they pass inbetween the light shielding bodies 101 to be photoelectrically converted into electrons E1 to E3 by the photosensitive element 102, as shown in FIG. 15(b), not all of the electrons E1 to E3 are accumulated in the region of the photosensitive element 102. The electron E1 enters a region of an adjacent photosensitive element 102. As a result, the electron E1 will have a different wavelength band (color) and have a different place for photoelectric conversion, resulting in a mixture of colors. Such a mixture of colors is caused by various other factors, and results in worsening color reproducibility. On the other hand, correction of a signal produced as a result of a mixture of colors into a signal without the mixture of colors by signal processing will result in the increase in noise.

Another cause of the mixture of colors can be described with reference to FIG. 16. As shown in FIG. 16, X is a portion where borders of adjacent color filters 120 and 121 for respective pixels overlap with each other. The overlapping portion X can also be a cause to produce a mixture of colors.

Lenses for cameras and modules having smaller F values so that the lenses become brighter are increasing. As the F value becomes smaller, the width of a light incident angle is widened, and the degree of instability increases as the distance from a microlens to a light receiving section for photoelectric conversion becomes longer. As a result, a mixture of colors increases.

As shown in FIG. 17, incident light from a lens 131 is oblique with respect to an optical axis AX in pixels (light receiving sections) in the peripheral portion of an imaging region 130, in which a plurality of light receiving sections are provided. Thus, the incident angle of the incident light is greater with respect to the optical axis AX at the pixels (light receiving sections) in the periphery than at the pixels (light receiving sections) in the center part of the imaging region 130.

On the other hand, the conventional solid-state imaging element 200 disclosed in Reference 2 relates to the object of improving the efficiency for preventing reflection and preventing the loss of incident light to improve the efficiency for a photoelectric conversion. In order to prevent a mixture of colors, only the light shielding member 206 is formed at the bottom part of the color filter 204 and inbetween adjacent color filters 204. Since the thickness of the light shielding member 206 is low, the mixture of colors may not be effectively restrained.

The present invention is intended to solve the conventional problems described above. The objective of the present invention is to provide: a solid-state imaging element, in which a distance between a lens and a substrate is shortened so that a correct signal can be received at a light receiving section and a mixture of colors can be effectively restrained; and an electronic information device, such as a camera-equipped cell phone device, including the solid-state imaging element as an image input device used in an imaging section thereof.

A solid-state imaging element according to the present invention includes a plurality of light receiving sections formed in a pixel array, each light receiving section constituted of a semiconductor element for performing a photoelectric conversion on and capturing an image of image light from a subject, the solid-state imaging element further including: a light shielding wall or a reflection wall provided therein for pixel separation, in between the light receiving sections adjacent to one another in a plan view on alight entering side from the light receiving sections; and a color filter wherein at least apart of the color filter is embedded between the light shielding walls or the reflection walls, in such a manner to correspond to each of the plurality of light receiving sections, so that the distance between the color filter and a substrate can be shortened, thereby achieving the objective described above.

Preferably, in a solid-state imaging element according to the present invention, the part of the color filter or all of the color filter is embedded between the light shielding walls or the reflection walls.

Still preferably, in a solid-state imaging element according to the present invention, a transparent joining film is formed in between the color filter and the light shielding walls or the reflection walls.

Still preferably, in a solid-state imaging element according to the present invention, a planarization film is provided above the plurality of light receiving sections, the light shielding walls or the reflection walls are provided in a grid form in a plan view above the planarization film, and the color filter is embedded in the light shielding wall or the reflection wall above the planarization film.

Still preferably, in a solid-state imaging element according to the present invention, a planarization film is provided above the plurality of light receiving sections, the light shielding walls or the reflection walls are provided in a grid form in a plan view above the planarization film, a transparent joining film is provided on the light shielding wall or the reflection wall and above the planarization film, and the color filter is embedded in a concave portion of the transparent joining film.

Still preferably, in a solid-state imaging element according to the present invention, the thickness of the light shielding wall or the reflection wall is one-half or more to equivalent to or less than, or three-quarters or more to equivalent to or less than the thickness of the color filter.

Still preferably, in a solid-state imaging element according to the present invention, the thickness of the light shielding wall or the reflection wall is one-fifth or more to one-half or less of the thickness of the color filter.

Still preferably, in a solid-state imaging element according to the present invention, the light shielding wall or the reflection wall is formed directly on the semiconductor substrate.

Still preferably, in a solid-state imaging element according to the present invention, the color filter is formed directly on the semiconductor substrate.

Still preferably, in a solid-state imaging element according to the present invention, a reflection preventing film is provided above the plurality of light receiving sections, the light shielding walls or the reflection walls are provided in a grid form in a plan view above the reflection preventing film, and the color filter is embedded in the light shielding wall or the reflection wall above the reflection preventing film.

Still preferably, in a solid-state imaging element according to the present invention, a reflection preventing film is provided above the plurality of light receiving sections, the light shielding walls or the reflection walls are provided in a grid form in a plan view above the reflection preventing film, a transparent joining film is provided on the light shielding wall or the reflection wall and above the reflection preventing film, and the color filter is embedded in a concave portion of the transparent joining film.

Still preferably, in a solid-state imaging element according to the present invention, at least either of the light shielding wall or reflection wall, or the color filter is formed in contact with a reflection preventing film laminated on the semiconductor substrate.

Still preferably, in a solid-state imaging element according to the present invention, the reflection preventing film is made of a silicon oxide film and a silicon nitride film, or a hafnium compound film.

Still preferably, in a solid-state imaging element according to the present invention, at least a part of the reflection wall or the light shielding wall is formed upwardly from a position 400 nm or less from a surface of the semiconductor substrate.

Still preferably, in a solid-state imaging element according to the present invention, the reflection wall or the light shielding wall is made of at least any of a metal, an alloy and a metal compound.

Still preferably, in a solid-state imaging element according to the present invention, the light shielding wall is made of a material which does not allow light to pass through it, and is any of W, Mo, Ti, Al, a compound thereof, and a black filter; and the reflection wall is any of Al, Al—Cu and Cu.

Still preferably, in a solid-state imaging element according to the present invention, the reflection wall or the light shielding wall is made of a material with a light absorbing coefficient higher than that of material in the periphery thereof.

Still preferably, in a solid-state imaging element according to the present invention, the reflection wall or the light shielding wall is made of a material with a refraction index of 1.3 to 1.5.

Still preferably, in a solid-state imaging element according to the present invention, the color filter or a filler filled together with the color filter is made of a material with a refractive index of 1.5 to 2.5.

Still preferably, in a solid-state imaging element according to the present invention, the reflection wall or the light shielding wall has a sectional shape which becomes thicker towards the side closer to the semiconductor substrate.

Still preferably, in a solid-state imaging element according to the present invention, the color filter or a filler filled together with the color filter is formed in a funnel shape.

Still preferably, in a solid-state imaging element according to the present invention, the solid-state imaging element is a back surface light emitting type, which allows light to enter from a back surface that is opposite from the side of a wiring layer used for signal reading or the like or a poly layer for propagating signals, with the light receiving section as a border.

Still preferably, in a solid-state imaging element according to the present invention, the reflection wall or the light shielding wall is electrically connected with the semiconductor substrate, and application of a predetermined voltage to the reflection wall or the light shielding wall enables application of a predetermined voltage to the semiconductor substrate.

Still preferably, in a solid-state imaging element according to the present invention, the reflection wall or the light shielding wall is grounded.

An electronic information device according to the present invention includes the solid-stage imaging element according to the present invention as an image input device in an imaging section thereof.

The functions of the present invention having the structures described above will be described hereinafter.

According to the present invention, the solid-state imaging element is formed such that a plurality of light receiving sections are formed therein in the form of a pixel array, each light receiving section constituted of a semiconductor element for performing a photoelectric conversion on and capturing an image of image light from a subject. In the solid-state imaging element, a light shielding wall or a reflection wall for pixel separation is provided in between adjacent light receiving sections in a plan view on the side from which light enters into the light receiving section. At least a part of a color filter is embedded in between the light shielding wall or reflection wall, in such a manner to correspond to each of the plurality of light receiving sections, in such a manner to reduce the distance between a color filter and a substrate.

Thus, the color filter is embedded into light shielding walls or reflection walls in a grid form, so that the light shielding walls or reflection walls need not be provided separately from the thickness (in the vertical direction with respect to the substrate surface) of the color filter. As a result, the distance between the microlens and the semiconductor substrate, and the distance between the color filter and the semiconductor substrate can be shortened. Owing to this shortened structure, a mixture of colors can be effectively restrained, and the light receiving sensitivity can also be increased in the light receiving sections. Therefore, a solid-state imaging element with a restrained mixture of colors and with high color reproducibility can be obtained. In addition, the effect of preventing a mixture of colors becomes greater and the light receiving sensitivity also becomes greater in the light receiving sections as the light shielding walls or reflection walls become closer to the semiconductor substrate.

According to the present invention with the structures described above, the color filters are embedded into the light shielding walls or reflection walls in a grid form so that the distance between the color filters and the substrate is reduced. As a result, the distance between the microlens and the semiconductor substrate, as well as the distance between the color filter and the semiconductor substrate can be shortened, thereby effectively restraining a mixture of colors and increasing the light receiving sensitivity in the light receiving sections. Thus, a solid-state imaging element with a restrained mixture of colors and with high color reproducibility can be obtained. In addition, the effect of preventing a mixture of colors becomes greater and the light receiving sensitivity also becomes greater in the light receiving sections as the light shielding walls or reflection walls become closer to the semiconductor substrate.

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross sectional view showing an example of an essential part structure of a solid-state imaging element according to Embodiment 1 of the present invention.

FIG. 2 is a longitudinal cross sectional view showing an example of a variation of the solid-state imaging element in FIG. 1.

FIG. 3 is a longitudinal cross sectional view further showing another example of a variation of the solid-state imaging element in FIG. 1.

FIG. 4 is a longitudinal cross sectional view showing an example of an essential part structure of a solid-state imaging element according to Embodiment 2 of the present invention. FIG. 4(a) is a longitudinal cross sectional view showing a case where a joining film is discontinuous. FIG. 4(b) is a longitudinal cross sectional view showing a case where a joining film is continuous.

FIG. 5 is a longitudinal cross sectional view showing an example of an essential part structure of a solid-state imaging element according to Embodiment 3 of the present invention.

FIG. 6 is a longitudinal cross sectional view showing an example of a variation of the solid-state imaging element in FIG. 5.

FIGS. 7(a) and 7(b) each are a longitudinal cross sectional view showing an example of an essential part structure of a solid-state imaging element according to Embodiment 4 of the present invention.

FIG. 8 is a longitudinal cross sectional view showing an example of a variation of the solid-state imaging elements in FIGS. 7(a) and 7(b).

FIG. 9 is a longitudinal cross sectional view showing an example of an essential part structure of a solid-state imaging element according to Embodiment 5 of the present invention.

FIG. 10 is a longitudinal cross sectional view showing an example of a variation of the solid-state imaging element in FIG. 9.

FIGS. 11(a) and 11(b) each are a diagram for explaining a funnel shape.

FIG. 12 is a block diagram schematically illustrating an exemplary configuration of an electronic information device as Embodiment 6 of the present invention, including the solid-state imaging elements according to any of Embodiments 1 to 5 of the present invention used in an imaging section thereof.

FIG. 13 is a plan view showing an example of an essential part structure of a conventional solid-state imaging element disclosed in Reference 1.

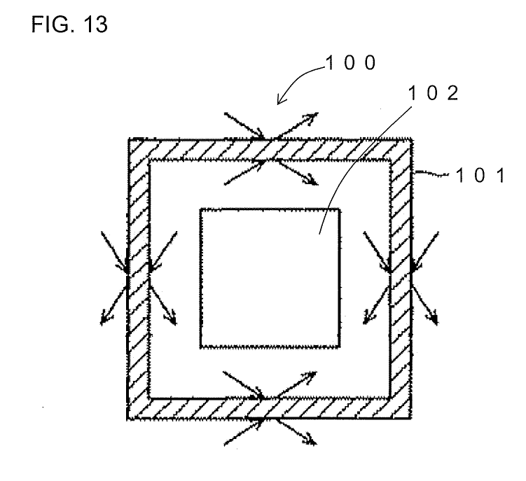

FIG. 14 is a longitudinal cross sectional view showing an example of an essential part structure of a conventional solid-state imaging element disclosed in Reference 2.

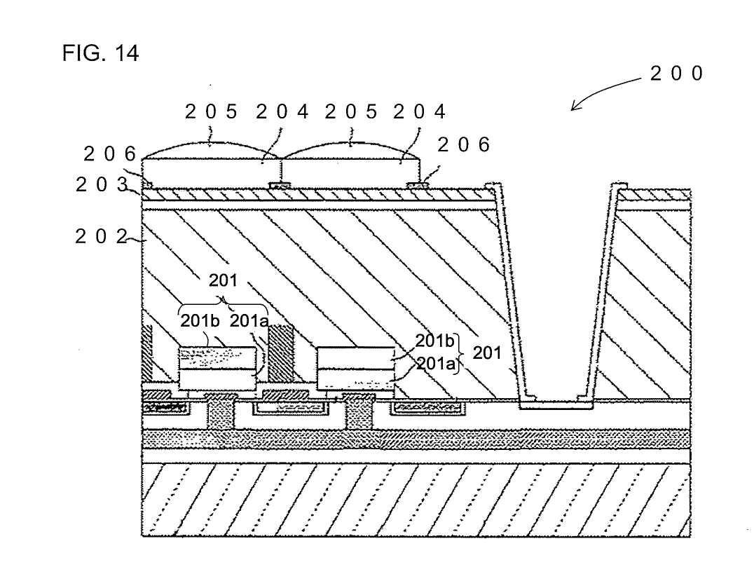

FIGS. 15(a) and 15(b) each are a longitudinal cross sectional view of an essential part, for explaining a mixture of colors in a conventional solid-state imaging element in FIG. 13.

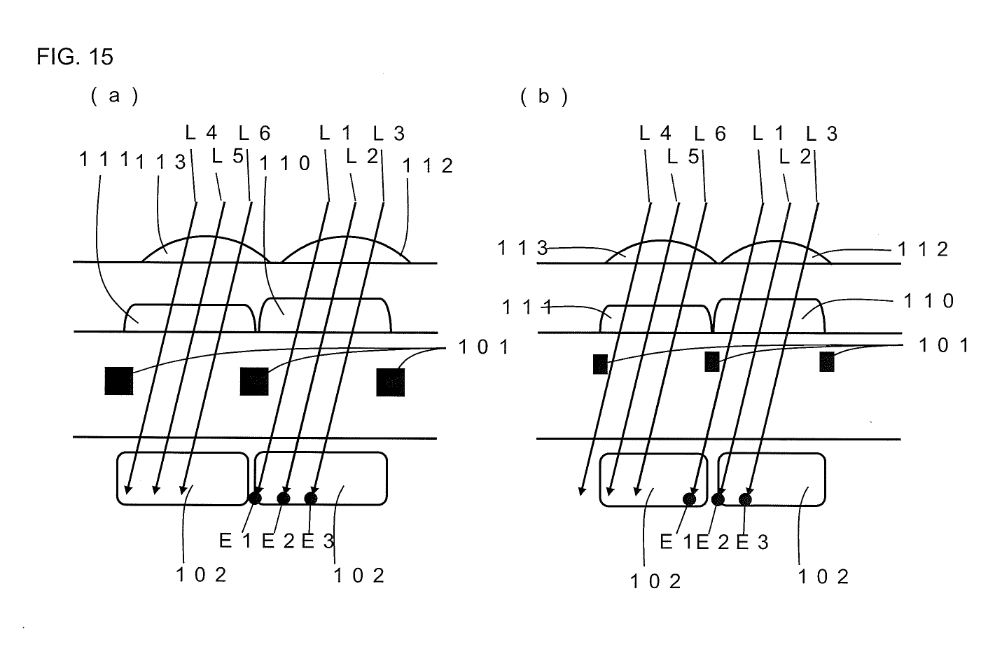

FIG. 16 is a longitudinal cross sectional view of an essential part, for explaining another cause (overlapping portion) of a mixture of colors different from that of FIG. 15.

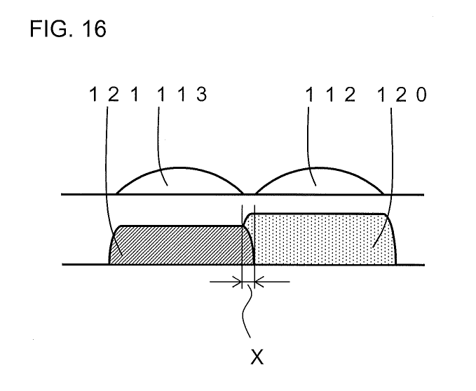

FIG. 17 is a longitudinal cross sectional view of an essential part, for explaining still another cause (oblique light) of a mixture of colors different from that of FIG. 15.

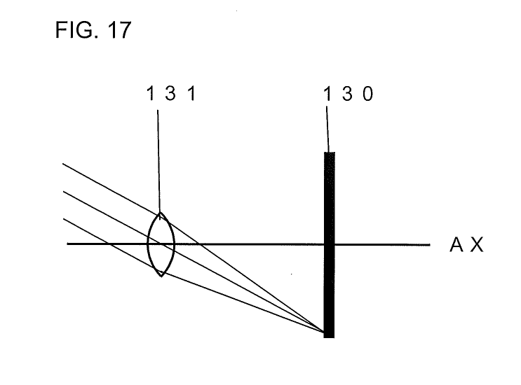

1, 1A, 1B, 11, 11A, 12, 12A, 13, 13A, 13B, 14, 14A solid-state imaging element
2 semiconductor substrate
3 light receiving section
4, 6 planarization film
4A reflection preventing film
4B reflection preventing film and joining film
5a, 5b color filter
7 microlens
8, 8A light shielding walls (or reflection walls)
9, 9A transparent joining film
10 transparent film (or SiO₂ film)
90 electronic information device
91 solid-state imaging apparatus
92 memory section
93 display section
94 communication section
95 image output section

### DESCRIPTION OF THE PREFERRED EMBODIMENTS

Hereinafter, Embodiments 1 to 5 of a solid-state imaging element according to the present invention, and Embodiment 6 of an electronic information device, such as a camera-equipped cell phone device, including the solid-state imaging element according to any of Embodiments 1 to 5 as an image input device used in an imaging section thereof will be described with reference to the accompanying figures. It should be noted that the thickness and length of each of the constituent members in the accompanying figures are not limited to those shown in the figures from the viewpoint of creating the figures.

### Embodiment 1

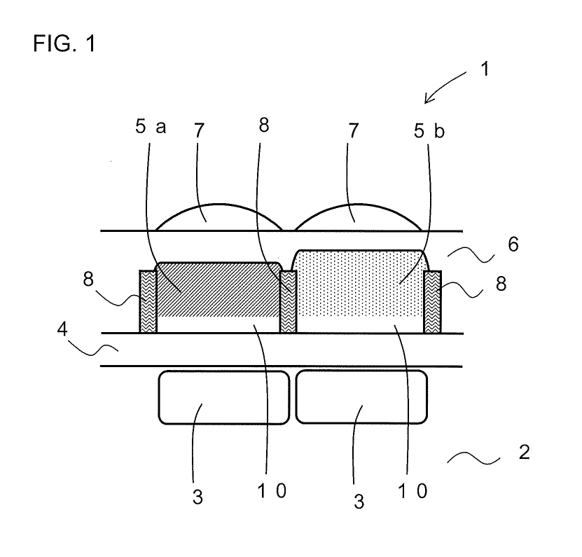

FIG. 1 is a longitudinal cross sectional view showing an example of an essential part structure of a solid-state imaging element according to Embodiment 1 of the present invention.

As shown in FIG. 1, a solid-state imaging element 1 according to Embodiment 1 includes a plurality of light receiving sections 3 arranged in a matrix in the upper part of a semiconductor substrate 2, the light receiving section 3 constituted of a semiconductor element for performing a photoelectric conversion on and capturing an image of image light from a subject. A color filter 5a or 5b is provided above each light receiving section 3, corresponding to each light receiving section 3, with a planarization film 4 and further a transparent film 10 (SiO₂ film) interposed therebetween. A microlens 7 is provided above each color filter 5a or 5b, corresponding to each light receiving section 3, with a planarization film 6 interposed therebetween. The microlens 7 focuses incident light onto each light receiving section 3. Each color filter 5a or 5b is any of the colors, R, G and B. Light shielding walls 8 (or reflection walls) are provided for optical separation in a grid form, at border portions of pixels (border portion of the color filter 5a or 5b), and the color filter 5a or 5b is embedded therebetween in such a manner to reduce the distance between the color filter and the substrate. The borders of the color filter 5a or 5b are partitioned by the light shielding walls 8 (or reflection walls). The thickness of the light shielding walls 8 (or reflection walls) in this case is less than the thickness of the color filter 5a or 5b and is three-quarters or more of the thickness of the color filter 5a or 5b.

The material for the light shielding wall 8 does not allow light to pass through it, and includes, for example, any of W, Mo, Ti, Al (aluminum) and a compound thereof, such as TiN (titanium nitride) and a black filter. The material for the reflection wall includes Al (aluminum), Al—Cu, and Cu.

In summary, in the light shielding wall 8 (or reflection wall), the light shielding material is a metal, an alloy, or a metal compound, so that light hitting the side wall can be reflected, thereby preventing the light receiving sensitivity from being decreased. In addition, when the light shielding material is a material with a high light absorbing coefficient, such as TiN (titanium nitride), and is allowed to absorb light, a mixture of colors can be prevented. Further, the use of a material with a refractive index lower than that of the color filter 5a or 5b or the material positioned on the side surface causes light to be reflected due to the difference of the refractive index between the material on the side where the light enters and the material of the side surface. Substantially all of the light arriving there is reflected. Thus, the light receiving sensitivity is hardly decreased, and a mixture of colors can be prevented. An effective material with low refractive index is a transparent oxide film with a refractive index of 1.3 to 1.5 (SiO₂ film: 1.4; acrylic resin oxide film: 1.45). In addition, light arriving there is also reflected with the use of a material with a high refractive index for the color filter 5a or 5b or the material positioned at the side surface. Thus, the light receiving sensitivity is hardly decreased, and a mixture of colors can be prevented. An effective material with high refractive index is a transparent acrylic resin material with a refractive index of 1.5 to 2.0 (or 2.5). Thus, as an optical waveguide structure, the material can allow light to be passed more effectively than metal.

In summary, the solid-state imaging element 1 according to Embodiment 1 is the one with a plurality of light receiving sections 3 formed in a pixel array, and a light shielding wall 8 (or reflection wall) for pixel separation is provided in between adjacent light receiving sections 3 on the light entering side of the light receiving sections 3. A part of the color filter 5a or 5b is embedded in between the light shielding walls 8 (or reflection walls), corresponding to each of the plurality of light receiving sections 3.

Therefore, according to the solid-state imaging element 1 according to Embodiment 1, the light shielding walls 8 in a grid form are provided at a pixel border portion of the border portion of the color filter 5a or 5b; the thickness between the microlens 7 and the semiconductor substrate 2 is lowered; and the thickness of the light shielding walls 8 (or reflection walls) is set to be three-quarters or more of the thickness (in the vertical direction with respect to the substrate surface) of the color filter 5a or 5b. As a result, a mixture of colors can be prevented more reliably, and color reproducibility can be improved. The effect of preventing a mixture of colors is greater and the light receiving sensitivity at the light receiving sections 3 is also greater as the distance is shorter between the light shielding wall 8 (or reflection wall) and the semiconductor substrate 2. In addition, the color filter 5a or 5b is formed to be embedded into the light shielding walls 8 (or reflection walls) in a grid form, so that the distance between the microlens 7 and the semiconductor substrate 2, and the distance between the color filter 5a or 5b and the semiconductor substrate 2 can be shortened. With such a structure, it becomes possible to restrain a mixture of colors effectively and the light receiving sensitivity at the light receiving section 3 can also be increased. Thereby, it becomes possible to manufacture the solid-state imaging element 1 with a restrained mixture of colors and with high color reproducibility.

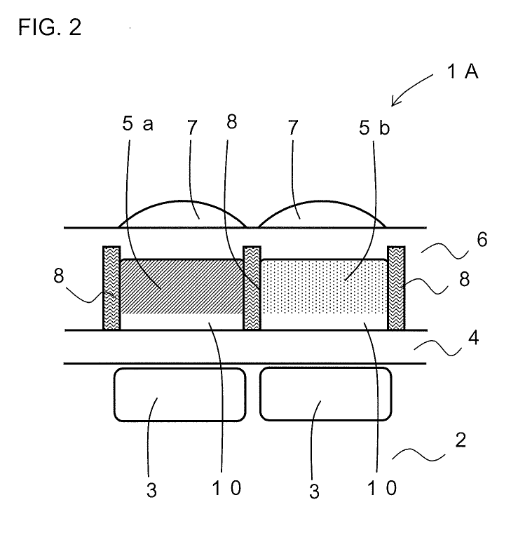

In Embodiment 1, the case has been described where a part of the color filter 5a or 5b is embedded in between adjacent light shielding walls 8 (or reflection walls) in such a manner to correspond to each of the plurality of light receiving sections 3, as shown in FIG. 1. However, without limitation to this case, the whole color filter 5a or 5b may be embedded in between adjacent light shielding walls 8 (or reflection walls) in such a manner to correspond to each of the plurality of light receiving sections 3, as shown in FIG. 2. This means that the color filter 5a or 5b may be completely embedded in the light shielding walls 8 (or reflection walls) in a grid form, as shown in FIG. 2. In summary, it is sufficient to embed at least a part of the color filter 5a or 5b in between the light shielding walls 8 (or reflection walls) in such a manner to correspond to each of the plurality of light receiving sections 3.

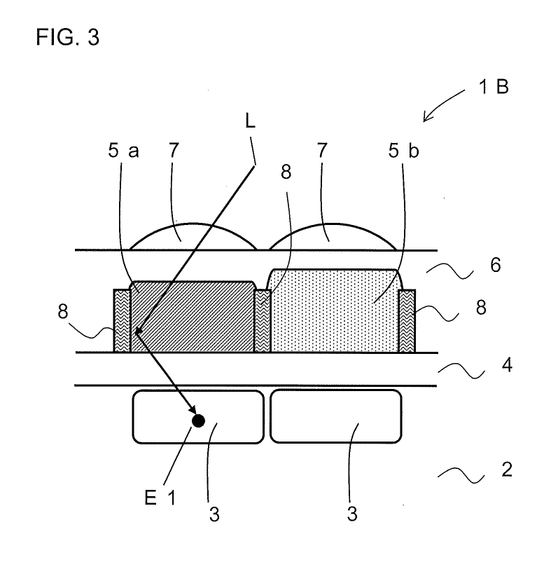

In FIGS. 1 and 2, the color filter 5a or 5b is provided above the planarization film 4 with the transparent film 10 (SiO₂ film) interposed therebetween. However, without limitation to this case, the color filter 5a or 5b may be provided immediately above the planarization film 4, as shown in FIG. 3, to be a solid-state imaging element 1B.

In Embodiment 1, the thickness of the light shielding walls 8 (or reflection walls) is lower than the thickness of the color filter 5a or 5b and is three-quarters or more of the thickness of the color filter 5a or 5b, as shown in FIG. 1. This is effective for restraining a mixture of colors. However, without limitation to this case, the thickness of the light shielding walls 8 (or reflection walls) may be lower than the thickness of the color filter 5a or 5b and may be one-half or more of the thickness of the color filter 5a or 5b. Further, the thickness of the light shielding walls 8 (or reflection walls) may be lower than the thickness of the color filter 5a or 5b and may be one-half or less of the thickness of the color filter 5a or 5b. The manufacturing is facilitated in this case. For example, the thickness of the light shielding walls 8 (or reflection walls) may be lower than the thickness of the color filter 5a or 5b and may be one-half or less and one-third, one-fourth or one-fifth or more of the thickness of the color filter 5a or 5b.

### Embodiment 2

In Embodiment 2, a case will be described in which a transparent joining film is provided in between light shielding walls 8 (or reflection walls) and a color filter 5a or 5b embedded therebetween, for joining them (e.g., metal and an organic film).

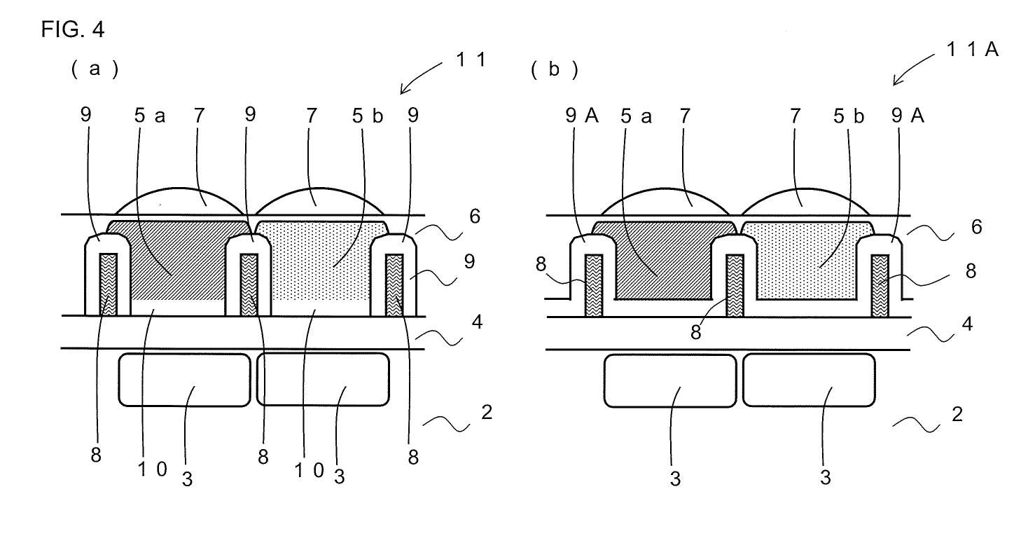

FIG. 4 is a longitudinal cross sectional view showing an example of an essential part structure of a solid-state imaging element according to Embodiment 2 of the present invention. FIG. 4(a) is a longitudinal cross sectional view showing a case where a joining film is discontinuous. FIG. 4(b) is a longitudinal cross sectional view showing a case where a joining film is continuous.

As shown in FIG. 4(a), a solid-state imaging element 11 according to Embodiment 2 includes a plurality of light receiving sections 3 arranged in a matrix in the upper part of a semiconductor substrate 2, the light receiving section 3 constituted of a semiconductor element for performing a photoelectric conversion on and capturing an image of image light from a subject. A color filter 5a or 5b is provided above each light receiving section 3, with a planarization film 4 and further a transparent film 10 (SiO₂ film) interposed therebetween, corresponding to each light receiving section 3. A microlens 7 is provided above each color filter 5a or 5b, corresponding to each light receiving section 3, with a planarization film 6 interposed therebetween. The microlens 7 focuses incident light onto each light receiving section 3. Each color filter 5a or 5b is any of the colors, R, G and B. Light shielding walls 8 (or reflection walls) are provided for optical separation in a grid form in a plan view, at border portions of pixels (border portion of the color filter 5a or 5b), and the color filter 5a or 5b is embedded in between the light shielding walls 8. The borders of the color filter 5a or 5b are partitioned by the light shielding walls 8 (or reflection walls). The thickness of the light shielding walls 8 (or reflection walls) in this case is less than the thickness of the color filter 5a or 5b and is one-half or more of the thickness of the color filter 5a or 5b. In this case, a transparent joining film 9 is provided in between the light shielding walls 8 (or reflection walls) and the color filter 5a or 5b embedded therein, for joining them.

The material for the light shielding wall 8 does not allow light to pass through it, and includes, for example, any of W, Mo, TiN (titanium nitride), Al (aluminum) and a black filter. The material for the reflection wall includes Al (aluminum) and Al—Cu.

In summary, in the light shielding wall 8 (reflection wall), the light shielding material is a metal, an alloy, or a metal compound, so that light at the side wall can be reflected, thereby preventing the light receiving sensitivity from being decreased. In addition, when the light shielding material is a material with a high light absorbing coefficient, such as TiN (titanium nitride), and is allowed to absorb light, a mixture of colors can be prevented. Further, the use of a material with a refractive index lower than that of the color filter 5a or 5b or the material positioned on the side surface causes light to be reflected due to the difference of the refractive index between the material on the side where the light enters and the material of the side surface. Substantially all of the light arriving there is reflected. Thus, the sensitivity is hardly decreased, and a mixture of colors can be prevented. An effective material with low refractive index has a refractive index of 1.5 or less. In addition, light arriving there is also reflected with the use of a material with a high refractive index for the color filter 5a or 5b or the material positioned at the side surface. Thus, the sensitivity is hardly decreased, and a mixture of colors can be prevented. An effective material with high refractive index has a refractive index of 1.5 or more.

In summary, the solid-state imaging element 11 according to Embodiment 2 is the one with a plurality of light receiving sections 3 formed in a pixel array, and a light shielding wall 8 (or reflection wall) for pixel separation is provided in between adjacent light receiving sections 3 on the light entering side of the light receiving sections 3. A part of the color filter 5a or 5b is embedded, corresponding to each of the plurality of light receiving sections 3, after the light shielding wall 8 (or reflection wall) is covered with the joining film 9. In this case, the transparent joining film 9 is provided in between the light shielding wall 8 (or reflection wall) and the color filter 5a or 5b, so that the light shielding wall 8 (or reflection wall) and the color filter 5a or 5b have good adhesion with one another with the transparent joining film 9 interposed therebetween, and the light shielding wall 8 (or reflection wall) and the color filter 5a or 5b cannot be peeled off from one another. Since the transparent joining film 9 is thin, there is no deterioration of light properties.

In Embodiment 2, the transparent joining film 9 is provided discontinuously inbetween the light shielding wall 8 (or reflection wall) and the color filter 5a or 5b, and is not provided above the planarization film 4. However, without limitation to this case, light shielding walls 8 (or reflection walls) in a grid form may be formed above the planarization film 4 and a transparent joining film 9A may be formed within the grid, for a variation of Embodiment 2, a solid-state imaging element 11A, as shown in FIG. 4(b). In this case, the transparent joining film 9A is formed from the upper surface and side surface of the light shielding wall 8 (or reflection wall) to above the planarization film 4. For the material of the transparent joining film 9A, any transparent material can be used in between the color filter 5a or 5b and the light shielding wall 8 (or reflection wall) as long as they can be adhered to one another. In FIG. 4(b), the color filter 5a or 5b may be directly provided above the transparent joining film 9A, and a transparent film 10 (SiO₂ film) may or may not be provided.

In summary, for a variation of Embodiment 2, a solid-state imaging element 11A, the planarization film 4 is provided above the plurality of light receiving sections 3, and the light shielding wall 8 (or reflection wall) are provided in a grid form in a plan view, above the planarization film 4. The transparent joining film 9A is provided above the planarization film 4 and on the light shielding wall 8 (or reflection wall), and the color filter 5a or 5b is embedded in a concave portion of the transparent joining film 9A.

### Embodiment 3

In Embodiment 3, a case will be described where a light shielding wall 8 (or reflection wall) and/or a color filter 5a or 5b are provided directly on a semiconductor substrate 2.

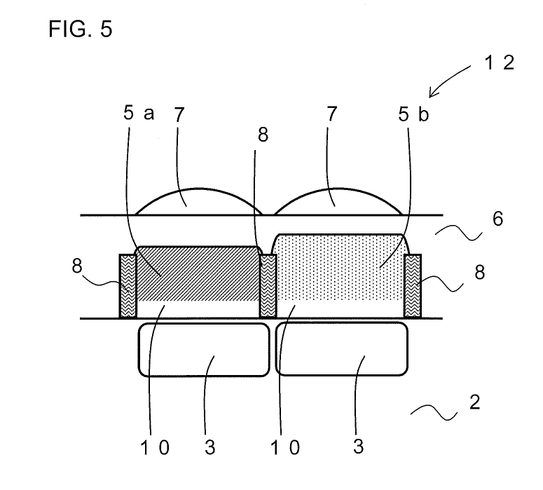

FIG. 5 is a longitudinal cross sectional view showing an example of an essential part structure of a solid-state imaging element according to Embodiment 3 of the present invention.

As shown in FIG. 5, a solid-state imaging element 12 according to Embodiment 3 includes a plurality of light receiving sections 3 arranged in a matrix in the upper part of a semiconductor substrate 2, the light receiving section 3 constituted of a semiconductor element for performing a photoelectric conversion on and capturing an image of image light from a subject. The light receiving sections 3 are formed in the semiconductor substrate 2, and a color filter 5a or 5b is provided directly on the semiconductor substrate 2 (without a planarization film 4 interposed therebetween), corresponding to each light receiving section 3, with a transparent film 10 interposed therebetween. A microlens 7 for focusing incident light on the light receiving section 3 is provided above the color filter 5a or 5b, corresponding to each light receiving section 3, with a planarization film 6 interposed therebetween. Each color filter 5a or 5b is any of the colors, R, G and B. Light shielding walls 8 (or reflection walls) for optical separation are provided in a grid form in a plan view at border portions of pixels (border portion of the color filter 5a or 5b) of the semiconductor substrate 2, and the color filter 5a or 5b is embedded therebetween. The border of the color filter 5a or 5b is partitioned by the light shielding wall 8 (or reflection wall). In this case, the thickness of the light shielding wall 8 (or reflection wall) is lower than the thickness of the color filter 5a or 5b and is three-quarters or more of the thickness of the color filter 5a or 5b.

The material for the light shielding wall 8 does not allow light to pass through it, and includes, for example, any of W, Mo, Al (aluminum) and a compound thereof as well as a black filter. The material for the reflection wall includes Al (aluminum), Al—Cu, and Cu.

Thus, according to the solid-state imaging element 12 according to Embodiment 3, the light shielding walls 8 (or reflection walls) in a grid form are provided directly above the semiconductor substrate 2 without the planarization film 4 interposed therebetween, and the color filter 5a or 5b is provided with the transparent film 10 interposed therebetween. Thus, the thickness between the microlens 7 and the semiconductor substrate 2 can be further lowered, thereby preventing a mixture of colors more reliably and improving color reproducibility. The effect of preventing a mixture of colors is greater and the light receiving sensitivity at the light receiving sections 3 is also greater as the distance is shorter between the light shielding wall 8 (or reflection wall) and the semiconductor substrate 2. In summary, the color filter 5a or 5b is embedded in the light shielding wall 8 (or reflection wall) in a grid form and the planarization film 4 is not provided, so that the distance between the microlens 7 and the semiconductor substrate 2, as well as the distance between the color filter 5a or 5b and the semiconductor substrate 2 can be further shortened. With this structure, it becomes possible to restrain a mixture of colors more effectively and increase the light receiving sensitivity at the light receiving sections 3 even more. Therefore, it becomes possible to manufacture the solid-state imaging element 12 with a restrained mixture of colors and with high color reproducibility.

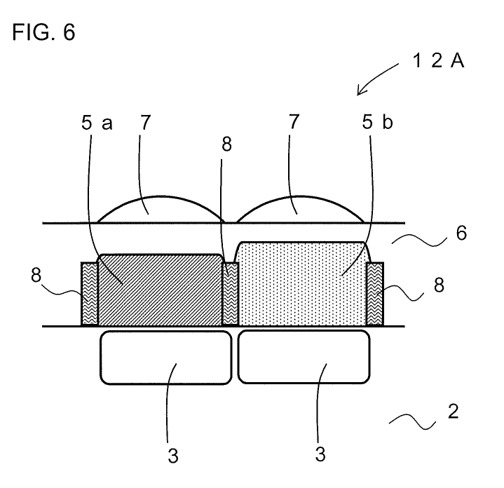

In Embodiment 3, the light shielding walls 8 (or reflection walls) are formed directly on the semiconductor substrate 2, and the color filter 5a or 5b is formed above the semiconductor substrate 2 with the transparent film 10 interposed therebetween. However, without limitation to this case, the light shielding walls 8 (or reflection walls) may be formed directly above the semiconductor substrate 2 and the color filter 5a or 5b may also be formed directly above the semiconductor substrate 2 for a solid-state imaging element 12A, as shown in FIG. 6. In summary, the transparent film 10 (SiO₂ film) is not provided in between the color filter 5a or 5b and the semiconductor substrate 2.

### Embodiment 4

In Embodiment 4, a case will be described where a light shielding wall 8 (or reflection wall) and a color filter 5a or 5b are provided above a semiconductor substrate 2 with a reflection preventing film interposed therebetween.

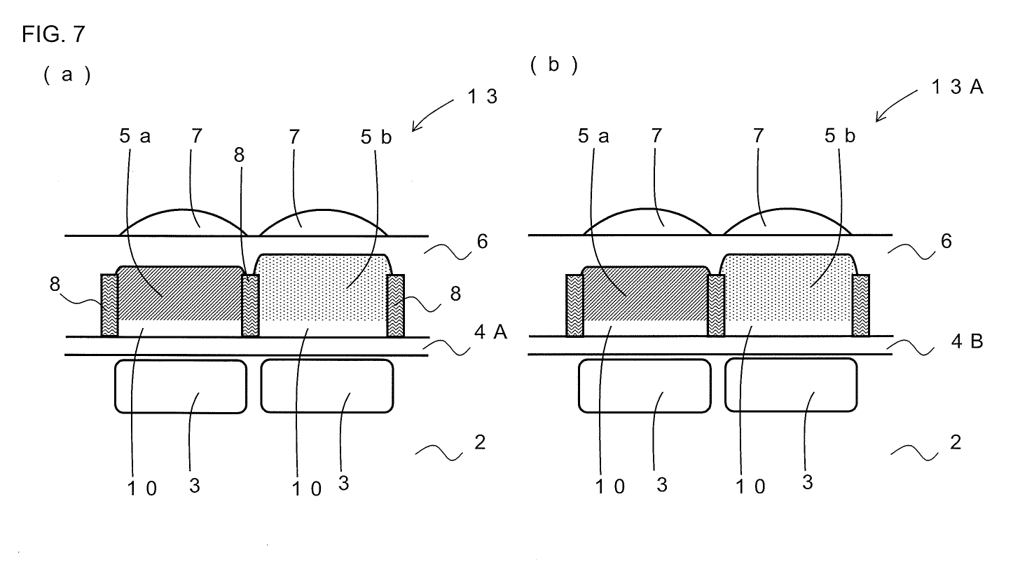

FIGS. 7(a) and 7(b) each are a longitudinal cross sectional view showing an example of an essential part structure of a solid-state imaging element according to Embodiment 4 of the present invention.

As shown in FIG. 7(a), a solid-state imaging element 13 according to Embodiment 4 includes a plurality of light receiving sections 3 arranged in a matrix in the upper part of a semiconductor substrate 2, the light receiving section 3 constituted of a semiconductor element for performing a photoelectric conversion on and capturing an image of image light from a subject. A reflection preventing film 4A is provided above the semiconductor substrate 2, in which the light receiving sections 3 are formed. Further, a color filter 5a or 5b is provided above the reflection preventing film 4A, corresponding to each light receiving section 3, with a transparent film 10 (or SiO₂ film) interposed therebetween. A microlens 7 is provided above each color filter 5a or 5b, corresponding to each light receiving section 3, with a planarization film 6 interposed therebetween. The microlens 7 focuses incident light onto each light receiving section 3. Each color filter 5a or 5b is any of the colors, R, G and B. Light shielding walls 8 (or reflection walls) are provided for optical separation in a grid form in a plan view, at border portions of pixels (border portion of the color filter 5a or 5b) of the semiconductor substrate 2, and the color filter 5a or 5b is embedded in between the light shielding walls 8. The borders of the color filter 5a or 5b are partitioned by the light shielding walls 8 (or reflection walls). The thickness of the light shielding walls 8 (or reflection walls) in this case is less than the thickness of the color filter 5a or 5b and is three-quarters or more of the thickness of the color filter 5a or 5b.

In summary, the reflection preventing film 4A is provided above the plurality of light receiving sections 3, and the light shielding walls 8 (or reflection walls) are provided in a grid form in a plan view above the reflection preventing film 4A. The color filter 5a or 5b are embedded in the light shielding walls 8 (or reflection walls) above the reflection preventing film 4A. The reflection preventing film 4A is formed of at least either of a silicon oxide film or a silicon nitride film.

The reflection preventing film 4A is made of a material with a refractive index ranging between that of the semiconductor substrate 2 with a high refractive index and an oxide film material or acrylic resin material. The reflection preventing film 4A is used to reduce reflection of light by incrementally changing a refractive index of the light passing therethrough. Particularly, the reflection preventing film 4A can be achieved with a silicon nitride film, an acrylic resin film, or a hafnium film. In summary, the reflection preventing film 4A is made of a silicon oxide film and a silicon nitride film, or a hafnium compound film.

The material for the light shielding wall 8 does not allow light to pass through it, and includes, for example, any of W, Mo, Al (aluminum) and a black filter. The material for the reflection wall includes Al (aluminum) and Al—Cu.

In Embodiment 4, as shown in FIG. 7(a), the case has been described where the reflection preventing film 4A is provided above the plurality of light receiving sections 3, the light shielding walls 8 (or reflection walls) are provided in a grid form in a plan view above the reflection preventing film 4A, and the color filter 5a or 5b is embedded in the light shielding walls 8 (or reflection walls) above the reflection preventing film 4A. However, without limitation to this case, the reflection preventing film 4A may be provided above the plurality of light receiving sections 3, the light shielding walls 8 (or reflection walls) may be provided in a grid form in a plan view above the reflection preventing film 4A, a transparent joining film 9A may be provided on the light shielding walls 8 (or reflection walls) and above the reflection preventing film 4A, and the color filter 5a or 5b may be embedded in a concave portion of the transparent joining film 9A. In addition, without limitation to this case, as shown in FIG. 4(a), a transparent joining film 9 may be provided instead of the transparent joining film 9A, and the transparent joining film 9 may be provided discontinuously between the light shielding walls 8 (or reflection walls) and the color filter 5a or 5b, and the transparent joining film 9 may not be provided above the planarization film 4.

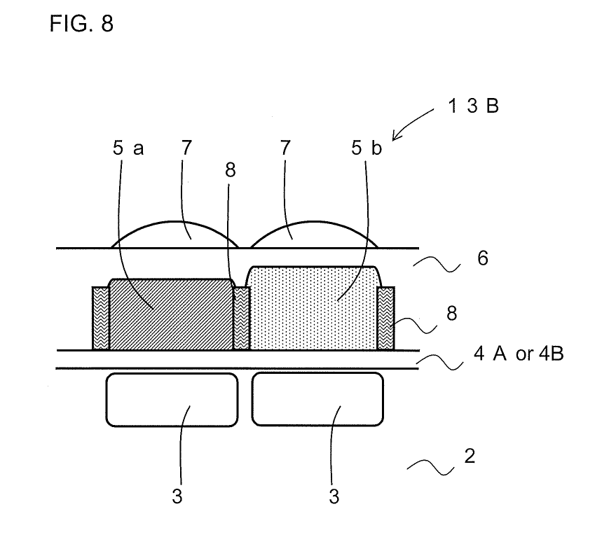

In Embodiment 4, as shown in FIG. 7(a), the case has been described where the reflection preventing film 4A is provided above the plurality of light receiving sections 3, the light shielding walls 8 (or reflection walls) are provided in a grid form in a plan view above the reflection preventing film 4A, and the color filter 5a or 5b is embedded in the light shielding walls 8 (or reflection walls) above the reflection preventing film 4A. However, without limitation to this case, a reflection preventing film and joining film 4B may be used instead of a reflection preventing film 4A, as shown in FIG. 7(b). In these cases, at least either of the light shielding walls 8 (or reflection walls) or the color filter 5a or 5b may be formed in such a manner as to be in contact with the reflection preventing film 4A or the reflection preventing film and joining film 4B, laminated on the semiconductor substrate 2. As illustrated in FIG. 8, the transparent film 10 (or SiO₂ film) may not be provided between the reflection preventing film 4A and the color filter 5a or 5b.

In addition, a film containing the transparent joining film 9 may be used instead of the reflection preventing film and joining film 4B shown in FIG. 7(b). In doing so, a mixture of colors can be appropriately restrained by forming the light shielding walls 8 (or reflection walls) upwardly from a position 400 nm or less from the surface of the semiconductor substrate 2. The upper limit position of the light shielding walls 8 (or reflection walls) is not specifically designated due to facilitating the manufacturing and relationship with the microlens 7.

### Embodiment 5

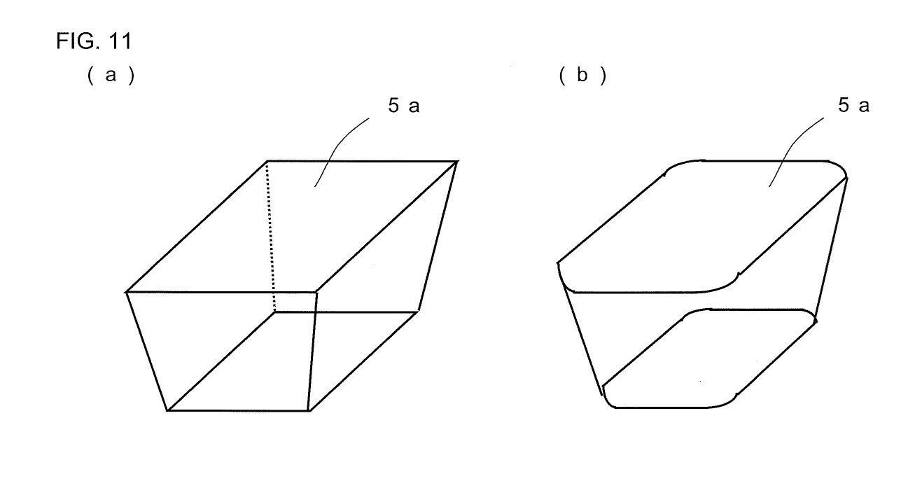

In Embodiment 5, a case will be described where a color filter 5a or 5b and a filler (transparent film 10) to be embedded are formed in a funnel shape to be described later and as shown in FIG. 11.

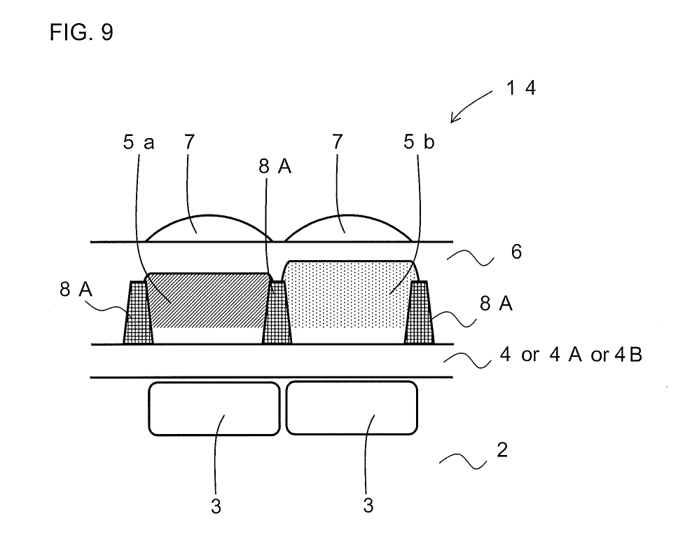

FIG. 9 is a longitudinal cross sectional view showing an example of an essential part structure of a solid-state imaging element according to Embodiment 5 of the present invention.

As shown in FIG. 9, a solid-state imaging element 14 according to Embodiment 5 includes a plurality of light receiving sections 3 arranged in a matrix in the upper part of a semiconductor substrate 2, the light receiving section 3 constituted of a semiconductor element for performing a photoelectric conversion on and capturing an image of image light from a subject. A planarization film 4 or reflection preventing film 4A is provided above the semiconductor substrate 2, in which the light receiving sections 3 are formed. A color filter 5a or 5b is provided above the planarization film 4 or reflection preventing film 4A, corresponding to each light receiving section 3, with a transparent film 10 (or SiO₂ film) interposed therebetween. A microlens 7 is provided above each color filter 5a or 5b, corresponding to each light receiving section 3, with a planarization film 6 interposed therebetween. The microlens 7 focuses incident light onto each light receiving section 3. Each color filter 5a or 5b is any of the colors, R, G and B. Light shielding walls 8A (or reflection walls) are provided for optical separation in a grid form in a plan view, at border portions of pixels (at the border portion of the color filter 5a or 5b) of the semiconductor substrate 2, and the color filter 5a or 5b is embedded in between the light shielding walls 8A. The borders of the color filter 5a or 5b are partitioned by the light shielding walls 8A (or reflection walls). Also in this case, side walls of the light shielding walls 8A (or reflection walls) are tapered and the tip portions are thinly formed. The thickness of the light shielding walls 8A (or reflection walls) in this case is less than the thickness of the color filter 5a or 5b and is three-quarters or more of the thickness of the color filter 5a or 5b. The light shielding walls 8A (or reflection walls) become thinner towards their tip portions (upper part), and are formed to be thicker towards the semiconductor substrate 2. On the other hand, the color filter 5a or 5b embedded in the light shielding walls 8A (or reflection walls) in a grid form is formed in a funnel shape as shown in FIGS. 11(a) and 11(b). The color filter 5a or 5b in FIG. 11(a) becomes the one in FIG. 11(b) by removing the corners and being rounded.

In summary, the planarization film 4 or reflection preventing film 4A is provided above the plurality of light receiving sections 3, the light shielding walls 8A (or reflection walls) with a thin upper end are provided in a grid form in a plan view, and the color filter 5a or 5b is embedded in a funnel shape with a thinner bottom part in the light shielding walls 8 (or reflection walls) in a grid form above the planarization film 4 or reflection preventing film 4A. The reflection preventing film 4A is made of at least either of a silicon oxide film or a silicon nitride film.

The material for the light shielding wall 8 does not allow light to pass through it, and includes, for example, any of W, Mo, Al (aluminum) and a black filter. The material for the reflection wall includes Al (aluminum) and Al—Cu.

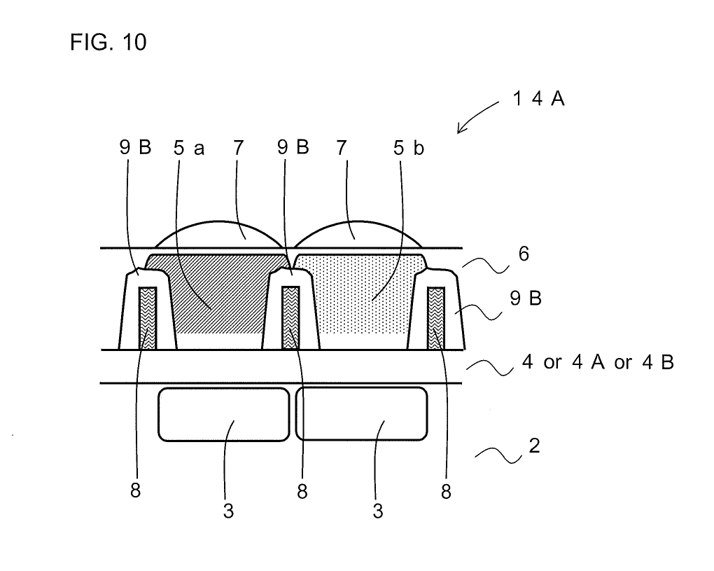

In Embodiment 5, as shown in FIG. 9, the case has been described where the planarization film 4 or reflection preventing film 4A is provided above the plurality of light receiving sections 3, the light shielding walls 8A (or reflection walls) are provided in a grid form in a plan view, and the color filter 5a or 5b is embedded in a funnel shape with a thinner bottom part, in the light shielding walls 8A (or reflection walls) in a grid form above the planarization film 4 or reflection preventing film 4A. However, without limitation to this case, the planarization film 4 or reflection preventing film 4A may be provided above the plurality of the light receiving sections 3, the light shielding walls 8 (or reflection walls) in a rib form may be provided in a grid form in a plan view above the planarization film 4 or reflection preventing film 4A, the transparent joining film 9A for joining metal and an organic film may be provided within the light shielding walls 8 (or reflection walls) in a grid form above the planarization film 4 or reflection preventing film 4A, and the color filter 5a or 5b may be embedded in a concave portion of the transparent joining film 9A with the transparent film 10 interposed therebetween. Alternatively, all of the color filters 5a or 5b may be embedded in the concave portion without the transparent film 10 interposed therebetween. In doing so, as shown in FIG. 10, the section of the transparent joining film 9B covering the light shielding walls 8 may be thinner towards the upper portion of its tip, and the color filter 5a or 5b embedded therein may be a funnel shape with a thinner bottom part. Without limitation to this case, the section of the transparent joining film 9B covering the light shielding walls 8 may be thinner towards its tip upper portion, and the transparent joining film 9B may be provided discontinuously between the light shielding walls 8 (or reflection walls) and the color filter 5a or 5b, and the transparent joining film 9B may not be provided above the planarization film 4, as shown in FIG. 10.

In Embodiment 5, as previously stated, the case has been described where the planarization film 4 or reflection preventing film 4A is provided above the plurality of light receiving sections 3, the light shielding walls 8 (or reflection walls) are provided in a grid form in a plan view, and the color filter 5a or 5b is embedded in a funnel shape with a thinner bottom part, in the light shielding walls 8A (or reflection walls) in a grid form above the planarization film 4 or reflection preventing film 4A. However, without limitation to this case, a reflection preventing film and joining film 4B may be used instead of a reflection preventing film 4A. The reflection preventing film and joining film 4B is a laminated film obtained by forming a joining film on a reflection preventing film.

In Embodiment 5, the color filter 5a or 5b is formed in a funnel shape as shown in FIGS. 11(a) and 11(b); however, without limitation to this form, a film for joining the color filter 5a or 5b can be thinner towards the semiconductor substrate 2. When a waveguide is formed with the color filter 5a or 5b or the film for joining, this funnel shape is more desirable.

In Embodiments 1 to 5, the application is particularly effective for a solid-state imaging element of a back surface light emitting type, in which light is not transmitted in between wiring layers. The distance between a lens and a substrate can be further shortened.

Although not particularly described in Embodiments 1 to 5, it is also possible to form a light shielding material with metal or the like and connect the material with the semiconductor substrate 2 to apply voltage to the semiconductor substrate 2. As a result, the flexibility of the wiring is improved. In addition, it is also possible to make a connection to ground, as a matter of course.

### Embodiment 6

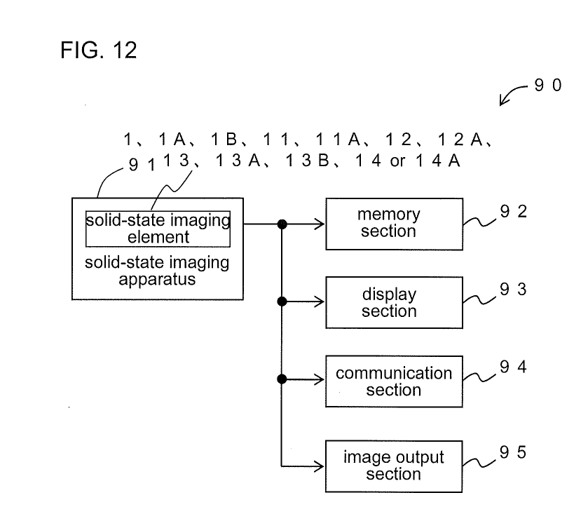

FIG. 12 is a block diagram schematically illustrating an exemplary configuration of an electronic information device as Embodiment 6 of the present invention, including the solid-state imaging elements 1, 1A, 1B, 11, 11A, 12, 12A, 13, 13A, 13B, 14 or 14A according to any of Embodiments 1 to 5 of the present invention used in an imaging section thereof.

In FIG. 12, an electronic information device 90 according to Embodiment 6 of the present invention includes: a solid-state imaging apparatus 91 for performing predetermined signal processing on an imaging signal from the solid-state imaging elements 1, 1A, 1B, 11, 11A, 12, 12A, 13, 13A, 13B, 14 or 14A according to any of Embodiments 1 to 5 so as to obtain a color image signal; a memory section 92 (e.g., recording media) for data-recording the color image signal from the solid-state imaging apparatus 91 after predetermined signal processing is performed on the color image signal for recording; a display section 93 (e.g., a liquid crystal display apparatus) for displaying the color image signal from the solid-state imaging apparatus 91 on a display screen (e.g., liquid crystal display screen) after predetermined signal processing is performed on the color image signal for display; a communication section 94 (e.g., a transmitting and receiving device) for communicating the color image signal from the solid-state imaging apparatus 91 after predetermined signal processing is performed on the color image signal for communication; and an image output section 95 (e.g., a printer) for printing the color image signal from the solid-state imaging apparatus 91 after predetermined signal processing is performed for printing. Without limitation to this case, the electronic information device 90 may include at least any of the memory section 92, the display section 93, the communication section 94, and the image output section 95 such as a printer, other than the solid-state imaging apparatus 91.

As the electronic information device 90, an electronic device that includes an image input device is conceivable, such as a digital camera (e.g., digital video camera or digital still camera), an image input camera (e.g., a monitoring camera, a door phone camera, a camera equipped in a vehicle including a vehicle back view monitoring camera, or a television telephone camera), a scanner, a facsimile machine, a camera-equipped cell phone device and a portable digital assistant (PDA).

Therefore, according to Embodiment 6 of the present invention, the color image signal from the sensor module 91 can be: displayed on a display screen properly; printed out on a sheet of paper using an image output section 95; communicated properly as communication data via a wire or wirelessly; stored properly at the memory section 92 by performing predetermined data compression processing; and further various data processes can be properly performed.

As described above, the present invention is exemplified by the use of its preferred Embodiments 1 to 6. However, the present invention should not be interpreted solely based on Embodiments 1 to 6 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 6 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of a solid-state imaging element comprising semiconductor elements for performing a photoelectric conversion on, and capturing an image of, image light from a subject; and an electronic information device, such as a digital camera (e.g., a digital video camera or a digital still camera), an image input camera (e.g., a monitoring camera), a scanner, a facsimile machine, a television telephone device and a camera-equipped cell phone device, including the solid-state imaging element as an image input device used in an imaging section. According to the present invention with the structures described above, the color filters are embedded into the light shielding walls or reflection walls in a grid form so that the distance between the color filters and the substrate is reduced. As a result, the distance between the microlens and the semiconductor substrate, as well as the distance between the color filter and the semiconductor substrate, can be shortened, thereby effectively restraining a mixture of colors and increasing the light receiving sensitivity at the light receiving sections. Thus, a solid-state imaging element with a restrained mixture of colors and with high color reproducibility can be obtained. In addition, the effect of preventing a mixture of colors becomes greater and the light receiving sensitivity also becomes greater in the light receiving sections as the light shielding walls or reflection walls become closer to the semiconductor substrate.

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state imaging element comprising a plurality of light receiving sections formed in a pixel array, each light receiving section constituted of a semiconductor element for performing a photoelectric conversion on and capturing an image of image light from a subject, the solid-state imaging element further comprising: a light shielding wall or a reflection wall provided therein for pixel separation, in between the light receiving sections adjacent to one another in a plan view on a light entering side from the light receiving sections; and a color filter wherein at least a part of the color filter is embedded between the light shielding walls or the reflection walls, in such a manner to correspond to each of the plurality of light receiving sections, so that the distance between the color filter and a substrate can be shortened.

2. A solid-state imaging element according to claim 1, wherein the part of the color filter or all of the color filter is embedded between the light shielding walls or the reflection walls.

3. A solid-state imaging element according to claim 1 or 2, wherein a transparent joining film is formed in between the color filter and the light shielding walls or the reflection walls.

4. A solid-state imaging element according to claim 1, wherein a planarization film is provided above the plurality of light receiving sections, the light shielding walls or the reflection walls are provided in a grid form in a plan view above the planarization film, and the color filter is embedded in the light shielding wall or the reflection wall above the planarization film.

5. A solid-state imaging element according to claim 1, wherein a planarization film is provided above the plurality of light receiving sections, the light shielding walls or the reflection walls are provided in a grid form in a plan view above the planarization film, a transparent joining film is provided on the light shielding wall or the reflection wall and above the planarization film, and the color filter is embedded in a concave portion of the transparent joining film.

6. A solid-state imaging element according to claim 1, wherein the thickness of the light shielding wall or the reflection wall is one-half or more to equivalent to or less than, or three-quarters or more to equivalent to or less than the thickness of the color filter.

7. A solid-state imaging element according to claim 1, wherein the thickness of the light shielding wall or the reflection wall is one-fifth or more to one-half or less of the thickness of the color filter.

8. A solid-state imaging element according to claim 1, wherein the light shielding wall or the reflection wall is formed directly on the semiconductor substrate.

9. A solid-state imaging element according to claim 1, wherein the color filter is formed directly on the semiconductor substrate.

10. A solid-state imaging element according to claim 1, wherein a reflection preventing film is provided above the plurality of light receiving sections, the light shielding walls or the reflection walls are provided in a grid form in a plan view above the reflection preventing film, and the color filter is embedded in the light shielding wall or the reflection wall above the reflection preventing film.

11. A solid-state imaging element according to claim 1, wherein a reflection preventing film is provided above the plurality of light receiving sections, the light shielding walls or the reflection walls are provided in a grid form in a plan view above the reflection preventing film, a transparent joining film is provided on the light shielding wall or the reflection wall and above the reflection preventing film, and the color filter is embedded in a concave portion of the transparent joining film.

12. A solid-state imaging element according to claim 1, wherein at least either of the light shielding wall or reflection wall, or the color filter is formed in contact with a reflection preventing film laminated on the semiconductor substrate.

13. A solid-state imaging element according to claim 10, wherein the reflection preventing film is made of a silicon oxide film and a silicon nitride film, or a hafnium compound film.

14. A solid-state imaging element according to claim 11, wherein the reflection preventing film is made of a silicon oxide film and a silicon nitride film, or a hafnium compound film.

15. A solid-state imaging element according to claim 12, wherein the reflection preventing film is made of a silicon oxide film and a silicon nitride film, or a hafnium compound film.

16. A solid-state imaging element according to claim 4, wherein at least apart of the reflection wall or the light shielding wall is formed upwardly from a position 400 nm or less from a surface of the semiconductor substrate.

17. A solid-state imaging element according to claim 5, wherein at least a part of the reflection wall or the light shielding wall is formed upwardly from a position 400 nm or less from a surface of the semiconductor substrate.

18. A solid-state imaging element according to claim 10, wherein at least apart of the reflection wall or the light shielding wall is formed upwardly from a position 400 nm or less from a surface of the semiconductor substrate.

19. A solid-state imaging element according to claim 11, wherein at least a part of the reflection wall or the light shielding wall is formed upwardly from a position 400 nm or less from a surface of the semiconductor substrate.

20. A solid-state imaging element according to claim 1, wherein the reflection wall or the light shielding wall is made of at least any of a metal, an alloy and a metal compound.

21. A solid-state imaging element according to claim 20, wherein the light shielding wall is made of a material which does not allow light to pass through it, and is any of W, Mo, Ti, Al, a compound thereof, and a black filter; and the reflection wall is any of Al, Al—Cu and Cu.

22. A solid-state imaging element according to claim 1, wherein the reflection wall or the light shielding wall is made of a material with a light absorbing coefficient higher than that of material in the periphery thereof.

23. A solid-state imaging element according to claim 1, wherein the reflection wall or the light shielding wall is made of a material with a refraction index of 1.3 to 1.5.

24. A solid-state imaging element according to claim 1, wherein the color filter or a filler filled together with the color filter is made of a material with a refractive index of 1.5 to 2.5.

25. A solid-state imaging element according to claim 1, wherein the reflection wall or the light shielding wall has a sectional shape which becomes thicker towards the side closer to the semiconductor substrate.

26. A solid-state imaging element according to claim 25, wherein the color filter or a filler filled together with the color filter is formed in a funnel shape.

27. A solid-state imaging element according to claim 1, wherein the solid-state imaging element is a back surface light emitting type, which allows light to enter from a back surface that is opposite from the side of a wiring layer used for signal reading or the like or a poly layer for propagating signals, with the light receiving section as a border.

28. A solid-state imaging element according to claim 1, wherein the reflection wall or the light shielding wall is electrically connected with the semiconductor substrate, and application of a predetermined voltage to the reflection wall or the light shielding wall enables application of a predetermined voltage to the semiconductor substrate.

29. A solid-state imaging element according to claim 28, wherein the reflection wall or the light shielding wall is grounded.

30. An electronic information device including the solid-stage imaging element according to claim 1 as an image input device in an imaging section thereof.
